(19) United States
(12) Patent Application Publication
(10) Pub. No.: US 2006/0187971 A1
(43) Pub. Date: Aug. 24, 2006

(54) Method and apparatus for concurrently transmitting a digital control signal and an analog signal from a sending circuit to a receiving circuit

(76) Inventors: Richard Kok Keong Lum, Singapore (SG); Ka Wal Lam, Singapore (SG)

Correspondence Address: AVAGO TECHNOLOGIES, LTD., P.O. BOX 1920, DENVER, CO, 80201-1920, US

(21) Appl. No.: 11/062,158

(22) Filed: Feb. 18, 2005

(51) Int. Cl. H04J 3/04; H04J 3/12; H03M 3/00

(52) U.S. Cl. 370/535; 370/528

(57) ABSTRACT

An apparatus and method for simultaneously transmitting a digital control signal and an analog signal from a sending circuit to a receiving circuit are described. An analog signal (e.g., a differential data signal) is received. A digital signal (e.g., a digital logic signal) is also received. The digital signal is then combined with the analog signal to generate an analog signal with an embedded digital signal. The analog signal with an embedded digital signal is then transmitted through a common communication link (e.g., a pair of conductors). The digital signal is then recovered from the analog signal with an embedded digital signal without affecting the recovery of the analog signal.

### BACKGROUND OF THE INVENTION

In today's competitive marketplace for electronic products, manufacturers must accommodate consumers' demand for products that are lighter, smaller, portable, and yet have an ever-increasing number of functions and features. In order to support this demand, a current trend in the research and development in semiconductor devices, microelectronics devices, and electronics devices is toward miniaturization, higher levels of integration, faster operating speeds, and lower power consumption.

It is noted that advances in packaging technology are required to provide devices and components to meet these trends. One promising packaging technology is referred to as chip scale package (CSP). For example, the wafer-level chip size packaging (WLCSP) or wafer-level chip scale packaging (WLCSP) conserves space by enabling a packaged CSP device size to occupy area that is only slightly (e.g., about 25%) larger than the area occupied by the die.

As the complexity of portable electronic systems, such as mobile handsets (e.g., cellular telephones), personal digital assistants (PDAs), portable computers, etc., has increased, more functions are being integrated into a single chip. Consequently, the concept of a system-on-a-chip (SoC) is evolving. However, there are significant challenges and difficulties of achieving a system-on-a-chip since there exists the daunting task of integrating different functions that may be designed by various different companies, each utilizing proprietary data bases, design rules, and intellectual properties (IP).

However, many benefits of SoC may be achieved by combining state-of-the-art WLP and CSP technologies to manufacture hybrid packaged integrated circuits (ICs) that have a small form. For example, by assembling two or more bare dies into various types of multichip modules (MCMs), a single packaged device may be realized. This single packaged device that includes multiple chips is referred to as a System-in-a-Package (SiP).

One advantage of the System-in-a-Package (SiP) is that the dies may be tested at the wafer-level by using, for example, the known good die (KGD) process. For multichip modules (MCM) and System-in-a-Package (SiP), wafer-level testing may be utilized to increase the packaging yield and save on packaging cost. Moreover, the cost and time for development of a system product are often reduced.

A typical System-in-a-Package (SiP) includes multiple integrated circuits (ICs) that are integrated in a single module or package. The individual functional integrated circuits (or chips) may be connected to each other by employing wires. For example, chip-to-chip bonding wires may be utilized to form the interconnections between and among the separate functional circuits or chips within the System-in-a-Package (SiP).

There are two main types of signals that are transmitted or communicated between and among the different functional chips. The first type of signal is a data signal that represents for example an analog data value. The second type of signal is a control signal that is utilized to control the processing of data signals, for example. As can be appreciated the number of bonding wires required to connect the various functional circuits or chips increases very rapidly since in addition to wires dedicated to data signals, there are separate and additional wires needed to transmit control signals between chips.

One challenge in the design of a System-in-a-Package (SiP) is to manage the number, layout, and routing of the chip-to-chip bonding wires. As the number of input signals and output signals (I/O signals) of device increases, the density of the interconnections increases, and the line width of each interconnection decreases. As can be appreciated, as the number of bonding wires increases, the complexity of the system and packaging problems increases proportionally. Moreover, as the number of bonding wires increases, the cost of packaging the integrated circuits or chips in the System-in-a-Package (SiP) increases, thereby increasing the overall cost of the System-in-a-Package (SiP).

Furthermore, as more functions and features are integrated into the System-in-a-Package (SiP), the number of input and output signals will inevitably continue to grow, and new solutions are needed to accommodate the increasing number of signals.

Based on the foregoing, there remains a need for a method and apparatus for transmitting signals that overcomes the disadvantages set forth previously.

### SUMMARY OF THE INVENTION

According to one embodiment of the present invention, a method and apparatus for simultaneously transmitting a digital control signal and an analog signal from a sending circuit to a receiving circuit are described. An analog signal (e.g., a differential data signal) is received. A digital signal (e.g., a digital logic signal) is also received. The digital signal is then combined with the analog signal to generate an analog signal with an embedded digital signal. The analog signal with an embedded digital signal is then transmitted through a common communication link (e.g., a pair of conductors). The digital signal is then recovered from the analog signal with an embedded digital signal without affecting the recovery of the analog signal.

### BRIEF DESCRIPTION OF THE DRAWINGS

The present invention is illustrated by way of example, and not by way of limitation, in the figures of the accompanying drawings and in which like reference numerals refer to similar elements.

FIG. 1 illustrates a System-in-a-Package (SiP) in which the signal transmission mechanism can be incorporated according to one embodiment of the invention.

FIG. 2 illustrates an exemplary multiplexing circuit that can be incorporated in the sending device according to one embodiment of the invention.

FIG. 3 is a block diagram illustrating a signal recovery circuit according to one embodiment of the invention.

FIG. 4 illustrates in greater detail an exemplary implementation of the positive common mode detector of FIG. 3 according to one embodiment of the invention.

FIG. 5 illustrates in greater detail an exemplary implementation of the negative common mode detector of FIG. 3 according to one embodiment of the invention.

FIG. 6 illustrates in greater detail an exemplary implementation of the zero crossing detector of FIG. 3 according to one embodiment of the invention.

FIG. 7 is a flowchart illustrating a method performed by the signal transmission mechanism according to one embodiment of the invention.

FIG. 8 is a timing diagram that illustrates a differential signal, common mode signal, synchronization signal, and binary data signal utilized by the signal transmission mechanism.

### DETAILED DESCRIPTION

A method and apparatus for simultaneously transmitting logic information (e.g., binary data or a digital signal) and an analog signal (e.g., a differential data signal) from a sending circuit to a receiving circuit are described. In the following description, for the purposes of explanation, numerous specific details are set forth in order to provide a thorough understanding of the present invention. It will be apparent, however, to one skilled in the art that the present invention may be practiced without these specific details. In other instances, well-known structures and devices are shown in block diagram form in order to avoid unnecessarily obscuring the present invention.

System-in-a-Package (SiP) 100

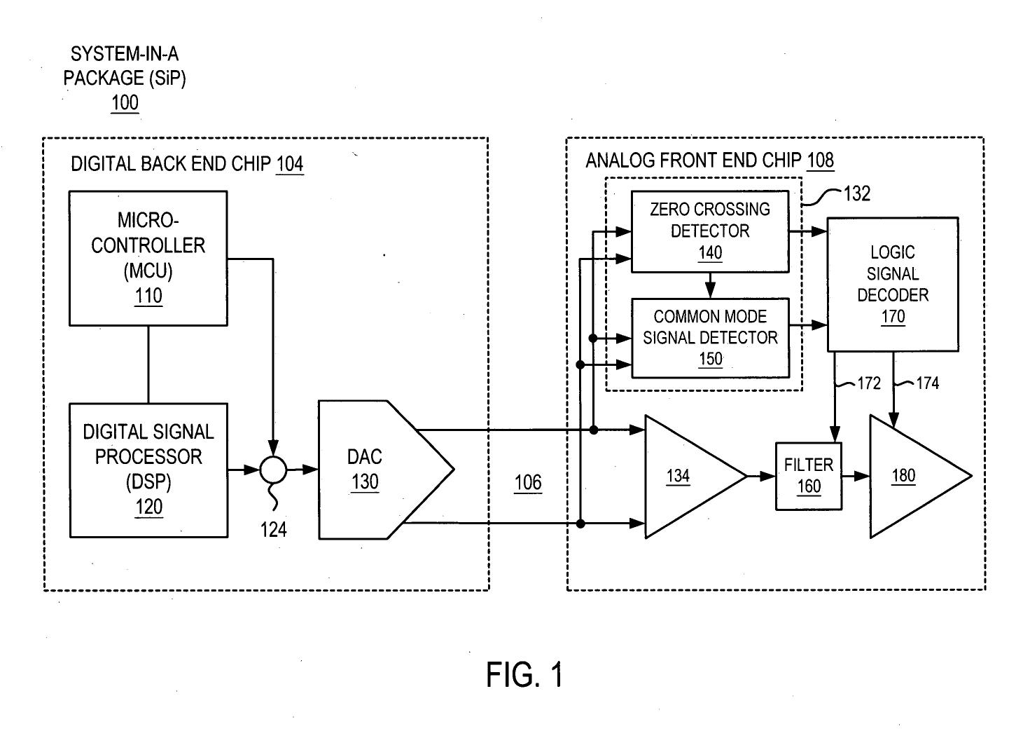

FIG. 1 illustrates a System-in-a-Package (SiP) 100 in which the signal transmission mechanism can be incorporated according to one embodiment of the invention. The System-in-a-Package (SiP) 100 includes multiple integrated circuits (ICs) that are integrated in a single package. One advantage of a System-in-a-Package (SiP) design is that the amount of space occupied by the system components may be conserved. In many cases, the amount of space and the layout may be substantially decreased as compared to implementing the system components individually without the System-in-a-Package (SiP). The System-in-a-Package (SiP) 100 can be a mulit-chip module that implements a communication system design.

The System-in-a-Package (SiP) 100 includes a first functional integrated circuit (hereinafter also referred to as a “first chip” or “first IC”) 104 and a second functional integrated circuit (hereinafter also referred to as a “second chip” or “second IC”) 108. The first functional integrated circuit 104 can be a digital back-end chip, and the second functional integrated circuit 108 can be an analog front-end chip. The first functional integrated circuit 104 and the second functional integrated circuit 108 communicate through an interface 106.

Interface 106 can be a communication link (e.g., a wired link or a wireless link). In one embodiment, interface 106 includes a pair of conductors (e.g., a differential pair of wires). In one embodiment, the interface 106 includes a plurality of conductors (e.g., chip-to-chip bonding wires) that may be utilized to form the interface or interconnections between and among the separate functional circuits or chips within the System-in-a-Package (SiP) 100.

The System-in-a-Package (SiP) 100 includes a signal transmission mechanism that according to one embodiment of the invention transmits a common mode signal (e.g., a binary data) and an analog signal (e.g., a differential data signal) from a sending circuit 104 to a receiving circuit 108 by utilizing a common communication link 106 (e.g., a differential pair). It is noted that System-in-a-Package (SiP) 100 can include other additional functional integrated circuits (not shown), and the signal transmission mechanism according to the invention may be implemented in two or more of these integrated circuits to facilitate the communication of information therebetween.

In one embodiment, components of the signal transmission mechanism according to the invention are incorporated in both the sending circuit (also referred to herein as the sending device or transmitting device) and the receiving circuit (also referred to herein as receiving device). For example, analog signals that represent data values are transmitted by employing a differential wire pair (hereinafter referred to also as “differential pair”). The differential pair can include a positive terminal (+ve terminal) and a negative terminal (-ve terminal). The analog front end (AFE) circuit includes receiving circuits that detect the signals received from the differential wire pair. One advantage of utilizing a differential wire pair to transmit signals (e.g., data signals) between the digital-to-analog converter (DAC) and the analog front end (AFE) circuit is that noise common to both conductors may be rejected.

The digital back-end chip 104 includes a micro-controller (MCU) 110, a digital signal processor (DSP) 120, and a digital-to-analog converter 130 (DAC) that converts digital signals into a corresponding analog signal. The MCU 110 and DSP 120 are programmed to perform operations required by the System-in-a-Package (SiP) 100. The construction and operation of the MCU 100 and the DSP 120 are known to those of ordinary skill in the art.

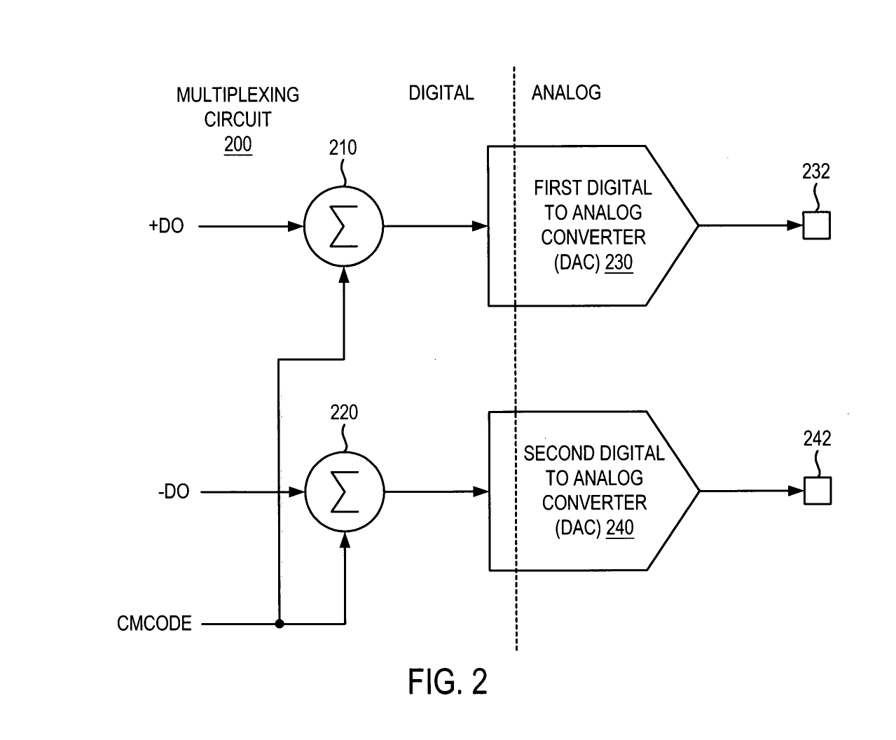

The digital back-end chip 104 also includes a mechanism 124 that combines a common mode signal (e.g., binary data or digital information) with an analog signal (e.g., a differential data signal). This mechanism 124 may be coupled to the MCU 110 and DSP 120 to receive information there from and coupled to the DAC 130 to provide information there to. This mechanism 124 is described in greater detail hereinafter with reference to FIG. 2. The chip 104 can also include other components and circuits (not shown) that perform digital back-end functions. It is noted that the construction and operation of these components are well-known to those of ordinary skill in the art and are not described herein.

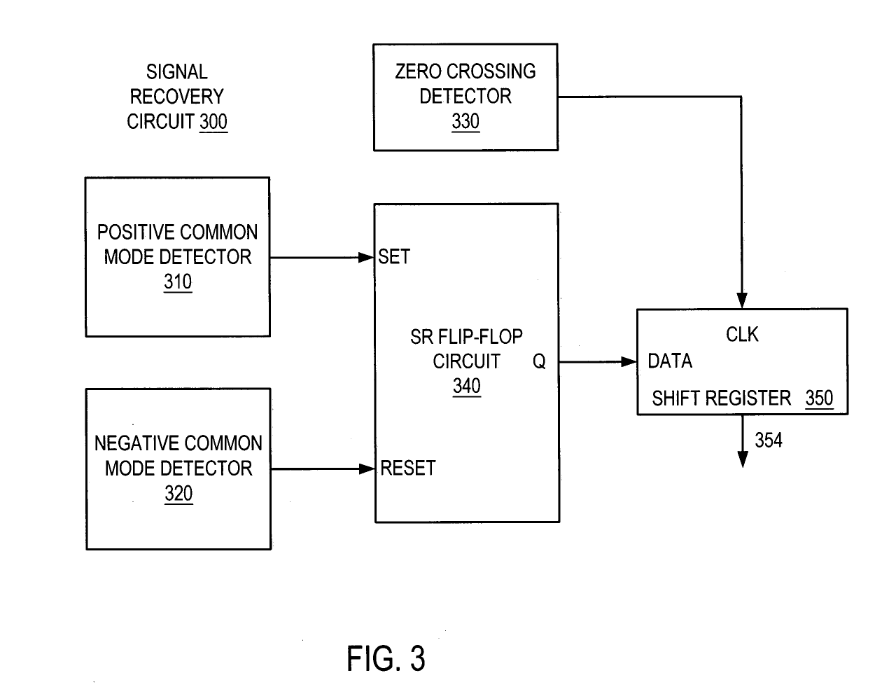

The analog front-end (AFE) chip 108 includes an amplifier 134 that is coupled to the interface 106 and that receives signals from the digital back-end chip 104. The AFE chip 108 also includes a filter 160 that is coupled to the output of the amplifier 134 and a line driver 180 that is coupled to the output of the filter 160. The construction and operation of the amplifier 134, filter 160, and line driver 180 are known to those of ordinary skill in the art. The AFE chip 108 also includes a mechanism 132 for extracting, de-multiplexing, or recovering the common mode signal that is embedded in the differential signal, which is transmitted by the chip 104 and received by the AFE 108. In one embodiment, this mechanism 132 includes a zero-crossing detector 140 and a common mode signal detector 150, which are described in greater detail hereinafter with reference to FIGS. 3-6.

The AFE chip 108 also includes a decoder 170 that receives the common mode signal and decodes the common mode signal (e.g., the binary data) to perform operations (e.g., control operations), such as a gain setting 174 and filter setting 172. The gain setting 174 (e.g., a variable gain setting) can be provided to a line driver 180. The filter setting 172 (e.g., a programmable filter pole setting) may be provided to a filter 160. The AFE chip 108 can also include other components and circuits (not shown) that perform analog front-end (AFE) functions. It is noted that the construction and operation of these components are well-known to those of ordinary skill in the art and are not described herein.

Simultaneous Transmission of Data and Control Signals

The signal transmission mechanism according to one embodiment of the invention advantageously enables data and control signals to be carried by a common communication link (e.g., by the same pair of conductors or a differential wire pair). In one embodiment, the signal transmission mechanism provides a multiplexing circuit 124 at the sending circuit (also referred to herein as a “transmitting device”) to embed logic information into an analog signal and a de-multiplexing circuit 132 at the receiving circuit to recover the logic information from the analog signal.

For example, the multiplexing circuit 124 combines, multiplexes or embeds a control signal (e.g., a digital signal) with a common mode signal (e.g., a differential signal). The de-multiplexing circuit 132 extracts, de-multiplexes or recovers the control signal without affecting the recovery of the common mode signal. A communication link (e.g., a wired or wireless link) is employed to simultaneously transmit the common mode signal (e.g., an analog data signal) and a digital signal (e.g., a control signal) between the sending device and the receiving device.

Some examples of signals that can be transmitted as common mode signals across two conductors include, but are not limited to, power-up configuration signals, zero-crossing detection signals, low-speed control signals, or any other signal that is not susceptible to common mode noise.

According to one embodiment of the invention, the signal transmission mechanism combines an analog signal (e.g., data signal) and one or more logic signals (e.g., digital control signals or status signals) and transmits the analog signal with combined logic signals across a common communication link (e.g., across a pair of conductors). The common communication link can be, for example, a differential pair, other wires or conductors, or a wireless communication link. Logic signals (e.g., control signals and status signals) are embedded into a differential analog data signal. The differential analog data signal with embedded logic signals is then transmitted between a transmitting circuit (e.g., a first integrated circuit) and a receiving circuit (e.g., a second integrated circuit) without affecting the recovery of the analog data signal. It is noted that the signal transmission mechanism according to one embodiment of the invention advantageously does not require separate conductors or additional conductors to transmit the logic signals, but instead utilizes the existing communication link that is employed to transmit the analog signal.

Exemplary Multiplexing Circuit 200 at the Sending Device

FIG. 2 illustrates an exemplary multiplexing circuit 200 that can be incorporated in the sending device according to one embodiment of the invention. The multiplexing circuit 200 includes a first summing circuit 210, a second summing circuit 220, a first digital-to-analog converter (DAC) 230, and a second digital-to-analog converter (DAC) 240.

The first summing circuit 210 includes a first input that receives a +DO signal, a second input that receives a CMCODE signal, and an output that generates an output signal. The first DAC 230 includes an input that is coupled to the output of the first summing circuit 210. The digital signal that is provided to the first DAC 230 is converted into a corresponding analog signal that can be, for example, a first component of a differential signal. The output of the first DAC 230 is coupled to the interface 106 (e.g., a first conductor 232).

The second summing circuit 220 includes a first input that receives a −DO signal, a second input that receives a CMCODE signal, and an output that generates an output signal. The second DAC 240 includes an input that is coupled to the output of the second summing circuit 220. The digital signal that is provided to the second DAC 240 is converted into a corresponding analog signal that can be a second component of a differential signal. The output of the second DAC 240 is also coupled to the interface 106 (e.g., a second conductor 242).

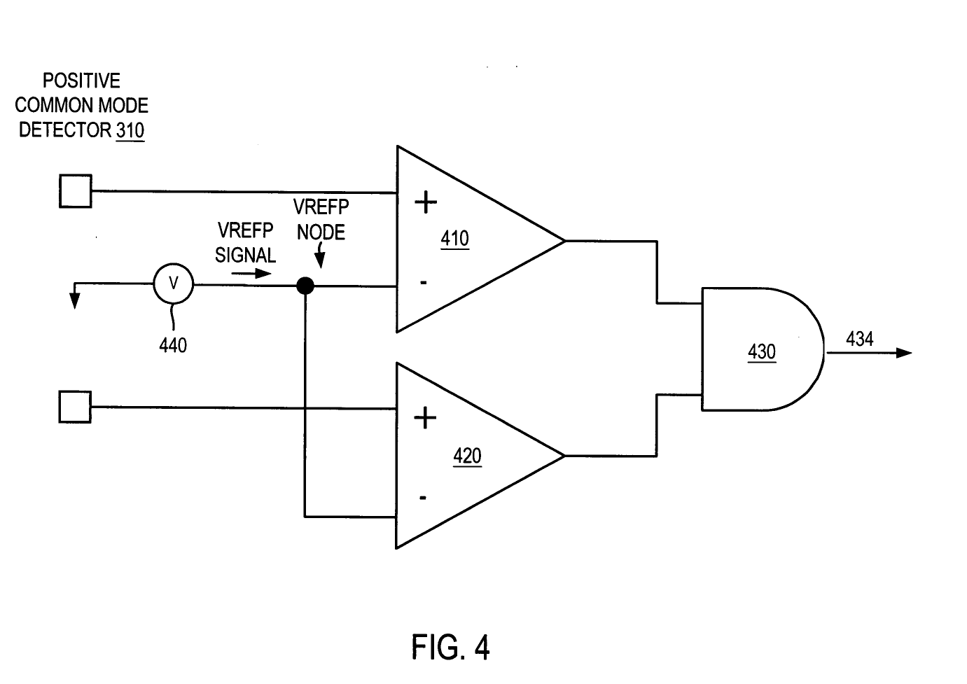

In one embodiment, the +DO signal and the −DO signal are digital codes of an analog waveform (e.g., an analog data signal) to be transmitted. In one embodiment, the CMCODE signal includes common mode information that is to be added to the analog waveform to be transmitted. For example, the CMCODE signal can be +B, −B, or zero, where B is a signal level (e.g. a voltage signal level) needed for the common mode detector 150 at the receiving circuit to correctly decode the common mode signal. Exemplary embodiments of a positive common mode detector 310 and a negative common mode detector 320 are described in greater detail hereinafter with reference to FIGS. 4 & 5, respectively.

Exemplary Signal Recovery Circuit 300

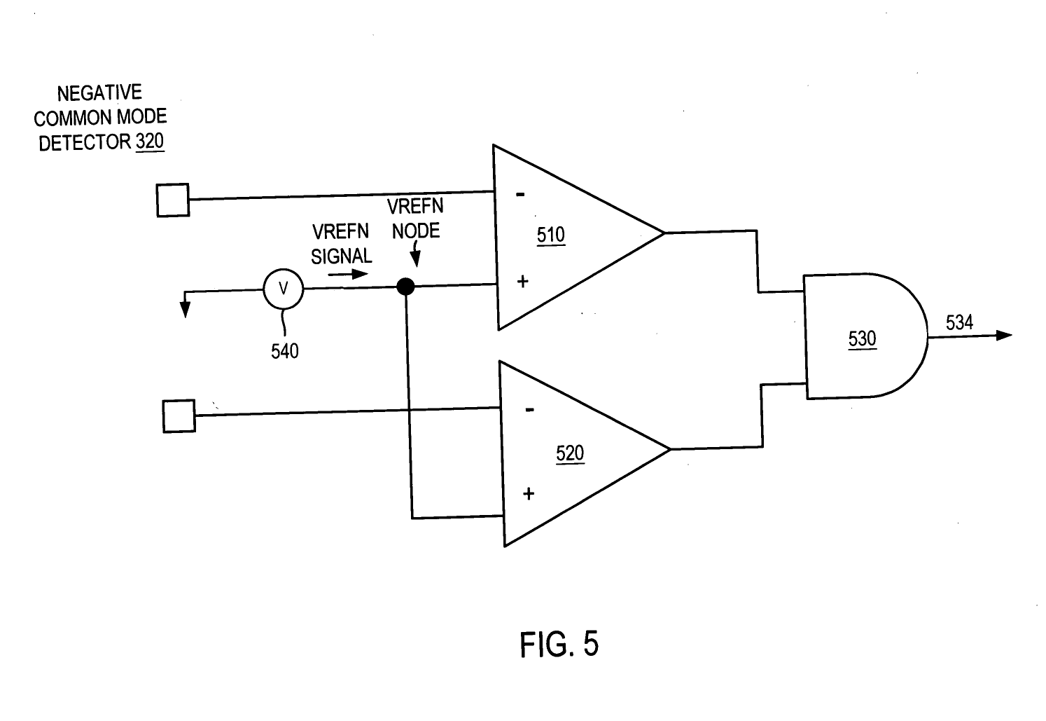

FIG. 3 is a block diagram illustrating a signal recovery circuit 300 according to one embodiment of the invention. The signal recovery circuit 300 includes a positive common mode detector 310 that detects positive common mode signals and generates an output signal. The signal recovery circuit 300 also includes a negative common mode detector 320 that detects negative common mode signals and generates an output signal. Exemplary embodiments of the positive common mode detector 310 and the negative common mode detector 320 are described in greater detail hereinafter with reference to FIG. 4 and FIG. 5, respectively.

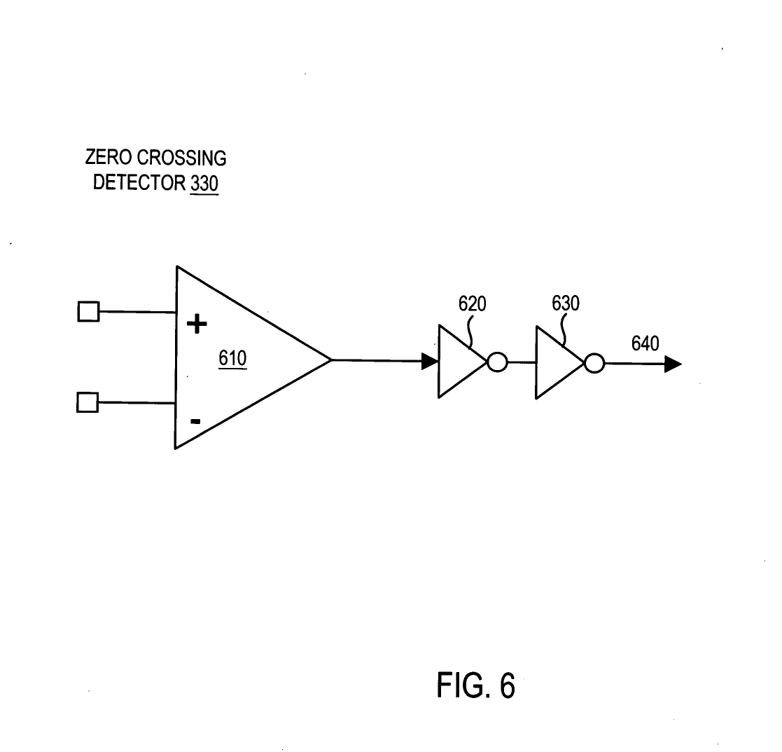

The signal recovery circuit 300 also includes a zero crossing detector 330 that detects zero crossings and generates an output signal. An exemplary implementation of the zero crossing detector 330 is described in greater detail hereinafter with reference to FIG. 6.

The signal recovery circuit 300 includes a SR flip-flop circuit 340 that includes a SET input that receives the output of the positive common mode detector 310, a RESET input that receives the output of the negative common mode detector 320, and a Q output that generates an output signal.

The signal recovery circuit 300 also includes a shift register circuit 350. The shift register circuit 350 includes a data input that receives the output of the SR flip-flop 340 and a clock input for receiving the output of the zero crossing detector 330. Based on these inputs, the shift register circuit 350 generates or recovers the control signals 354.

Positive Common Mode Detector 310

FIG. 4 illustrates in greater detail an exemplary implementation of the positive common mode detector 310 of FIG. 3 according to one embodiment of the invention. The positive common mode detector 310 includes a first amplifier 410, a second amplifier 420, and an AND gate 430. The first amplifier 410 includes a positive terminal that is coupled to a first conductor (e.g., conductor 232), a negative terminal that is coupled to a VREFP node that provides a predetermined signal (e.g., a VREFP signal), and an output that generates an output signal. It is noted that a voltage source 440 can be utilized to generate the VREFP signal.

The second amplifier 420 includes a negative terminal that is coupled to a second conductor (e.g., conductor 242), a negative terminal that is coupled to the VREFP node, and an output that generates an output signal. The AND gate 430 includes a first input that receives the output of the first amplifier 410, second input that receives the output of the second amplifier 420 and an output that generates an output signal 434 that represents the result of a logical AND operation on the two inputs. The output signal 434 is also referred to herein as the “positive common mode logic signal.” The positive common mode logic signal 434 is asserted (e.g., a logic high) when both the inputs goes above VREFP (e.g., when both input signals are greater than the VREFP signal).

In one embodiment, the predetermined signal (VREFP signal) is determined by the following expression: VREFP=VCM+VOFFSET. VCM is the common mode level of the incoming differential signal, and VOFFSET is selected for noise margin purposes. It is noted that the predetermined signal (VREFP) can be adjusted to suit the requirements of a particular application.

Negative Common Mode Detector 320

FIG. 5 illustrates in greater detail an exemplary implementation of the negative common mode detector 320 of FIG. 3 according to one embodiment of the invention. The negative common mode detector 320 includes a first amplifier 510, a second amplifier 520, and an AND gate 530. The first amplifier 510 includes a negative terminal that is coupled to a first conductor (e.g., conductor 232), a positive terminal that is coupled to a VREFN node that provides a predetermined signal (e.g., a VREFN signal), and an output for generating an output signal. It is noted that a voltage source 540 can be utilized to generate the predetermined signal (e.g., a predetermined voltage signal, VREFN signal).

The second amplifier 520 includes a negative terminal that is coupled to a second conductor (e.g., conductor 242), a positive terminal that is coupled to the VREFN node, and an output for generating an output signal. The AND gate 530 includes a first input that receives the output of the first amplifier 510, a second input that receives the output of the second amplifier 520 and an output that generates an output signal 534 that represents the result of a logical AND operation on the two inputs. The output signal 534, which is referred to also as the “negative common mode logic signal,” is asserted (e.g., a logic high) when both of the inputs goes below VRFFN signal (e.g., when both input signals are less than the VREFN signal).

In one embodiment, the predetermined signal (VREFN) is determined by the following expression: VREFN=VCM−VOFFSET. VCM is the common mode level of the incoming differential signal, and VOFFSET is selected for noise margin purposes. It is noted that the predetermined signal (VREFN) can be adjusted to suit the requirements of a particular application.

Zero Crossing Detector 330

FIG. 6 illustrates in greater detail an exemplary implementation of the zero crossing detector 330 of FIG. 3 according to one embodiment of the invention. The zero crossing detector 330 includes an analog comparator 610 that includes a positive terminal that is coupled to receive a first component of a differential signal, a negative terminal that is coupled to receive a second component of a differential signal, and an output that generates an output signal. In one embodiment, the positive terminal of the analog comparator 610 is coupled to a first conductor (e.g., conductor 232) of a differential pair, and the negative terminal of the analog comparator 610 is coupled to a second conductor (e.g., conductor 242) of the differential pair.

The zero crossing detector 330 also includes one or more buffers 620, 630 (e.g., CMOS buffers). The zero crossing detector 330 generates logic timing information 640 that is extracted from the received differential signal.

Processing Performed by the Signal Transmission Mechanism

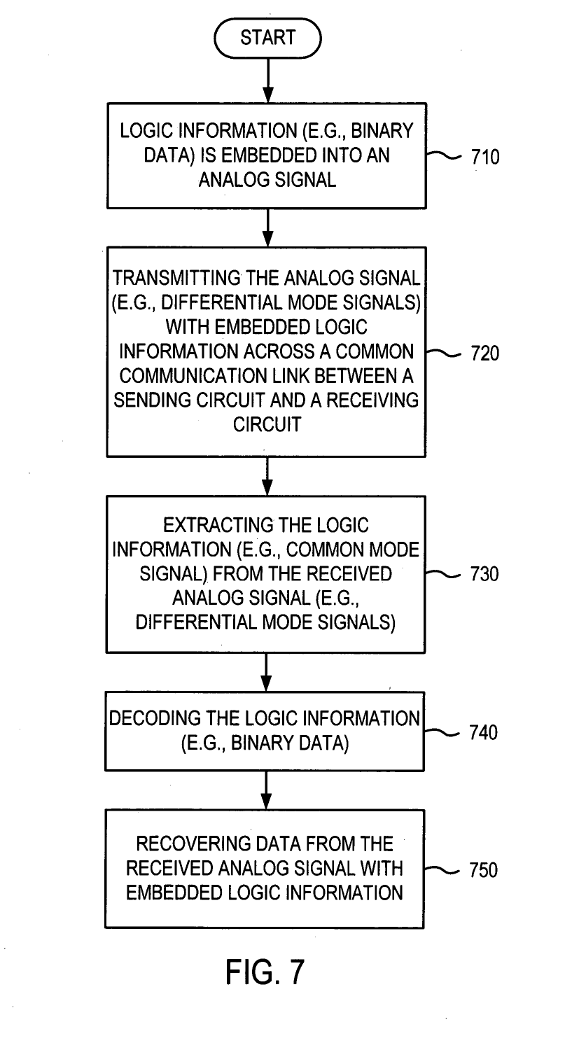

FIG. 7 is a flowchart illustrating a method performed by the signal transmission mechanism according to one embodiment of the invention. In step 710, logic information (e.g., binary data) is embedded into an analog signal. The logic information or binary data is also referred to herein as a common mode signal or as digital information (e.g., a logic 1 or a logic 0). For example, a digital signal (e.g., a logic 1 or logic zero) may be embedded in or multiplexed with differential data signals (e.g., a positive component and a negative component). In one embodiment, a common mode signal is multiplexed onto two conductors (e.g., a differential wire pair). A multiplexing unit 200 at a transmitting device can perform step 710. It is noted that step 710 can include the steps of receiving the logic information and of receiving the analog signal (e.g., a differential data signal).

In step 720, the analog signal (e.g., differential mode signals) with embedded logic information (e.g., a common mode signal) is transmitted across a common communication link between a sending circuit and a receiving circuit. For example, the logic information and the analog signal are simultaneously transmitted across the common communication link (e.g., two conductors or a differential pair).

In step 730, the logic information (e.g., common mode signal) is extracted from the received analog signal (e.g., differential mode signals) with embedded logic information. A de-multiplexing unit 132 at the receiving device can perform step 730. Step 730 can include the following sub-steps: 1) receiving the analog signal (e.g., differential mode signals) with embedded digital information; 2) using the received analog signal to generate a synchronization signal; and 3) extracting the digital information (e.g., common mode signal) extracted from received analog signal by utilizing the synchronization signal. It is noted that the synchronization signal may be generated by the zero-crossing detector 330, and the digital information may be extracted from the received analog signal by common mode signal detectors 310, 320.

In step 740, the logic information (e.g., binary data) is decoded by a control signal decoder 170, for example. The logic information or digital signal may be decoded and provided to program or control a circuit (e.g., a filter or line driver). For example, the logic information may be utilized as a gain setting, a filter pole setting, or as another control signal for a circuit at the receiving chip 108. In step 750, data is recovered from the received analog signal with embedded logic information (e.g., a differential mode signal with embedded logic). Step 750 can include the steps of rejecting the common mode signal (e.g., the embedded logic information) and recovering the analog signal (e.g., a differential data signal) from the received analog signal (e.g., differential mode signal). It is noted that the embedded logic information does not affect the processing of or the recovery of the data (e.g., an analog data signal) from the differential mode signal. Furthermore, it is noted that the control signal (e.g., digital codes) and analog signal (e.g., differential data signal) may be processed in a concurrent manner (e.g., a non-sequential manner).

Signal Transmission Mechanism Operation

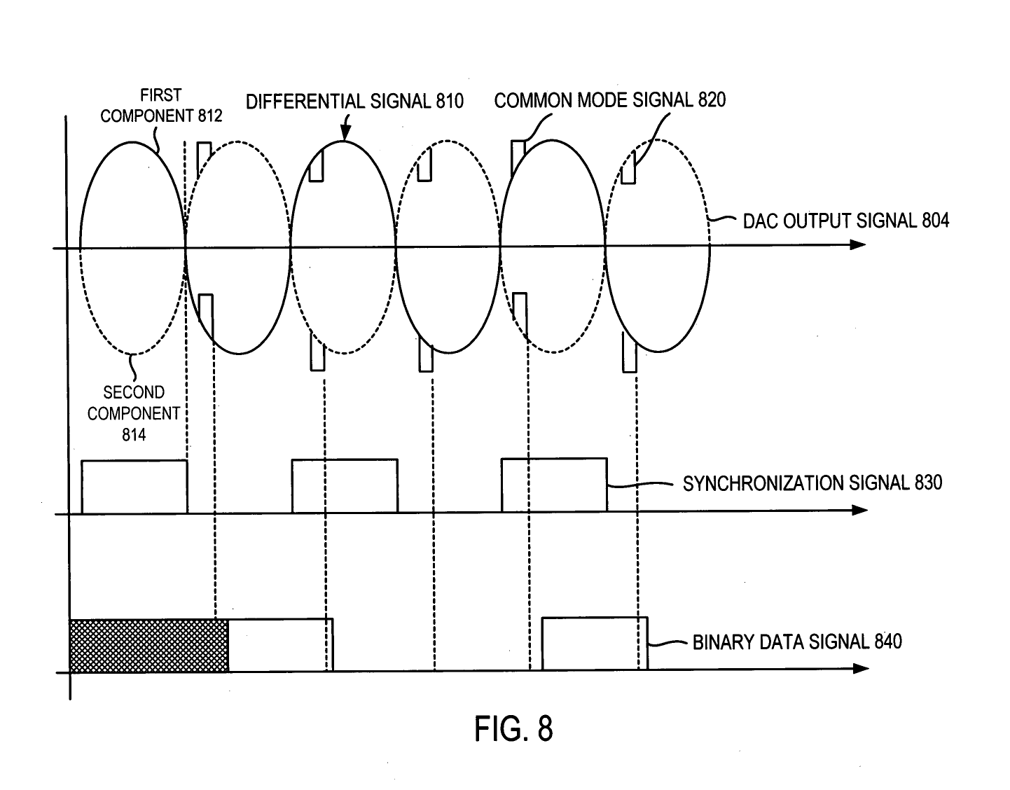

FIG. 8 is a timing diagram that illustrates exemplary signals (e.g., DAC output signal 804, a synchronization signal 830, and a binary data signal 840) utilized by the signal transmission mechanism according to one embodiment of the invention. The horizontal axis represents time. The first waveform 804 represents the output signal generated by the digital-to-analog converter (DAC). The first waveform 804 can include an analog signal 810 (e.g., a differential signal) and a common mode signal 820. The differential signal 810 can include a first component 812 (e.g., a positive component) and a second component 814 (e.g., a negative component).

For example, the common mode signal 820 can be embedded in the analog signal 810 in order to simultaneously or concurrently transmit binary data with the differential signal 810 from a sender (e.g., a digital back-end circuit) to a receiver (e.g., an analog front-end circuit). It is noted that the common mode signal 820 is rejected by a differential receiver and in this regard does not affect the normal processing of the differential signal 810 performed by the receiving circuit. The normal processing of the differential signal 810 at the receiving circuit is well-known by those of ordinary skill in the art and will not be described herein.

The second waveform 830 represents a synchronization signal that is generated by the zero-crossing detector 330. For example, the synchronization signal 830 is derived based upon the zero crossings of the positive and negative DAC output signal 804. The third waveform 840 represents binary data (e.g., a digital control signal) extracted from the DAC output signal 804 by the common mode signal detector 310, 320.

In one embodiment, the transmission method according to the invention can be implemented in a power line transceiver System-in-a-Package (SiP) that includes a communications encoder/decoder integrated circuit that performs digital signal processing and an analog front-end circuit that performs analog front end functions. The communications encoder/decoder integrated circuit and the analog front-end circuit are separate from each other and cannot be integrated into a single chip because different, incompatible manufacturing technologies are typically utilized to implement the respective integrated circuits.

For example, it is noted that the communications encoder/decoder integrated circuit requires high logic density to implement the digital signal processing (DSP) functions, and it typically manufactured by utilizing a deep sub-micron CMOS manufacturing process. However, the analog front-end (AFE) circuit requires high current and high voltage and is typically manufactured by employing a BiCMOS manufacturing process.

It is noted that the signal transmission method and apparatus according to the invention may be beneficial in any System-in-a-Package (SiP) or multi-chip module in which there are two or more integrated circuits (or chips) that may not be physically integrated due to the different manufacturing technologies utilized to realize the respective chips. One advantage of this approach is that additional conductors (e.g., wires) are not required to transmit the logic information (e.g., binary data). Stated differently, dedicated wires or conductors are not needed to transmit the logic information since the logic information is embedded with the analog signal (e.g., a differential data signal) according to the embodiments of the invention and transmitted through existing conductors previously dedicated to transmitting only analog data signals.

In the foregoing specification, the invention has been described with reference to specific embodiments thereof. It will, however, be evident that various modifications and changes may be made thereto without departing from the broader scope of the invention. The specification and drawings are, accordingly, to be regarded in an illustrative rather than a restrictive sense.

What is claimed is:

1. A System-in-a-Package (SiP) comprising:
a sending circuit that includes a multiplexer that combines logic information with an analog signal;
a receiving circuit; and
a communication link coupled to the sending circuit and the receiving circuit that simultaneously transmits the analog signal with logic information between the sending circuit and the receiving circuit;
wherein the receiving circuit includes a demultiplexer that extracts the logic information from the received signal without affecting the recovery of the analog signal.

2. The System-in-a-Package (SiP) of claim 1 wherein the multiplexer includes a first summing circuit that includes a first input that receives a positive digital code (+DO), a second input that receives common mode information (CMCODE) and an output, a second summing circuit that includes a first input that receives a negative digital code (−DO), a second input that receives common mode information (CMCODE) and an output, a first digital to analog converter that is coupled to the output of the first summing circuit, and a second digital to analog converter that is coupled to the output of the second summing circuit.

3. The System-in-a-Package (SiP) of claim 1 wherein the demultiplexer includes a zero crossing detection circuit, a positive common mode detector, and a negative common mode detector.

4. The System-in-a-Package (SiP) of claim 3 wherein the demultiplexer further includes a logic information decoder.

5. The System-in-a-Package (SiP) of claim 1 wherein the transmitting circuit includes a micro controller unit that provides the logic information and a digital signal processing unit that provides the analog signal.

6. The System-in-a-Package (SiP) of claim 1 wherein the control signal and the common mode signal are transmitted simultaneously from the transmitting device to the receiving device and the control signal and common mode signal are processed in a concurrent manner (i.e., non-sequential manner).

7. The System-in-a-Package (SiP) of claim 1 wherein the transmitting circuit is a digital back-end integrated circuit; and wherein the receiving circuit is an analog front-end integrated circuit.

8. The System-in-a-Package (SiP) wherein the analog signal includes a differential data signal; and wherein the binary data includes one of power-up configuration signals, zero-crossing detection signals, low-speed control signals, and other signals that are not susceptible to common mode noise.

9. The System-in-a-Package (SiP) of claim 1 wherein the communication link is one of a wireless link, a wired link, a conductor, and a pair of differential conductors.

10. An system for signal transmission across a common communication link comprising:
a multiplexer at a sending end that embeds binary data in an analog signal; and
a demultiplexer at a receiving end that extracts the binary data from the received analog signal; wherein the system does not affect the recovery of data from the received analog signal.

11. The system of claim 10 wherein the common communication is one of a wireless link, a wired link, a conductor, and a differential pair of conductors; wherein the analog signal includes a differential data signal and wherein the binary data includes one of power-up configuration signals, zero-crossing detection signals, low-speed control signals, and other signals that are not susceptible to common mode noise.

12. The system of claim 10 wherein the demultiplexer includes
a zero crossing detector that receives the analog signal and based thereon generates a synchronization signal; and
a common mode signal detector that extracts the binary data by utilizing the synchronization signal.

13. The system of claim 10 wherein the demultiplexer includes
a decoder that receives the extracted binary data and decodes the binary data.

14. The system of claim 10 wherein the multiplexer is implemented in a digital back end integrated circuit; and wherein the demultiplexer is implemented in an analog front end integrated circuit.

15. The system of claim 10 wherein the system is implemented in one of a System-in-a-Package (SiP) and a multi-chip module.

16. A method of communicating a signal between a sending circuit and a receiving circuit comprising:
embedding logic information into an analog signal;
the sending circuit transmitting the analog signal with logic information;
the receiving circuit receiving the analog signal with logic information; and
extracting the logic information from the received analog signal.

17. The method of claim 16 wherein embedding logic information into an analog signal includes:
receiving the logic information; and
receiving the analog signal.

18. The method of claim 16 wherein transmitting the analog signal with logic information includes:
transmitting the analog signal with logic information across a differential pair of conductors.

19. The method of claim 16 wherein extracting the logic information from the received analog signal includes:
utilizing the received analog signal to generate a synchronization signal;
extracting the logic information by employing the synchronization signal; and
decoding the logic information.

20. The method of claim 16 further comprising:
recovering a data signal from the received analog signal; and
rejecting the logic information that is a common mode signal.
